(19) United States
(12) Patent Application Publication
(10) Pub. No.: US 2022/0415626 A1
(43) Pub. Date: Dec. 29, 2022

(54) APPARATUS FOR TREATING SUBSTRATE AND METHOD FOR TREATING SUBSTRATE

(71) Applicant: SEMES CO., LTD., Cheonan-si (KR)

(72) Inventors: JIN HEE HONG, Hwaseong-si (KR); SUNG MIN CHOI, Osan-si (KR); YUN SANG KIM, Seongnam-si (KR); MIN SUNG JEON, Osan-si (KR); YOUNG EUN JEON, Ulsan (KR); DONG YOUNG JANG, Seongnam-si (KR)

(21) Appl. No.: 17/846,104

(22) Filed: Jun. 22, 2022

(30) Foreign Application Priority Data
Jun. 23, 2021 (KR) 10-2021-0081501

(51) Int. Cl. H01J 37/32; H01L 21/67

(52) U.S. Cl. CPC H01J 37/32724; H01J 37/32568; H01J 37/32449; H01L 21/67115; H01J 2237/334; H01J 2237/002; H01J 2237/2007

(57) ABSTRACT

The inventive concept provides a substrate treating apparatus. The substrate treating apparatus includes a chamber providing a treating space; a support unit supporting a substrate at the treating space; a gas supply unit configured to introduce a gas to the treating space; a plasma source configured to provide an energy for exciting a gas introduced to the treating space to a plasma; an exhaust unit configured to exhaust an atmosphere within the treating space to an outside of the treating space; and a heating source positioned above the support unit, and wherein the heating source applies a heating energy in a pulse form to the substrate.

### CROSS-REFERENCE TO RELATED APPLICATIONS

A claim for priority under 35 U.S.C. § 119 is made to Korean Patent Application No. 10-2021-0081501 filed on Jun. 23, 2021, in the Korean Intellectual Property Office, the entire contents of which are hereby incorporated by reference.

### BACKGROUND

Embodiments of the inventive concept described herein relate to a substrate treating apparatus and a substrate treating method.

An isotropic atomic layer etching is a method of removing a controlled amount of material in all directions, and performs an adsorption reaction for modifying a surface film and a desorption reaction for removing a modified film using a heat. A reaction temperature required for the adsorption reaction and the desorption reaction are different depending on a substrate type, and a precursor type used in the adsorption reaction or the desorption reaction. In general, the adsorption reaction is highly reactive at a low temperature (e.g., room temperature to 200° C.), and the desorption reaction is highly reactive at a very high temperature (e.g., 400° C. or higher).

However, when a substrate is heated using a conventional heater in an electrostatic chuck, it is difficult to separate and expose the substrate to an optimum temperature of the adsorption reaction and the desorption reaction, and thus the substrate is treated at a fixed temperature at which both the adsorption reaction and the desorption reaction are possible. As a result, both the adsorption reaction and the desorption reaction are possible, but as a process proceeds for a long time at the fixed temperature having a low reactivity, a UPH is lowered. In addition, if a temperature of the electrostatic chuck is heated excessively to a temperature of 500° C. or above to improve a reactivity, the substrate is exposed for a long time to a high temperature, thereby causing a damage such as a loss of a device function, a pattern collapsing, and a substrate cracking due to a molecular diffusion within an elaborately manufactured semiconductor structure.

On the other hand, there is also a method of overcoming the limitations of a hardware by mounting a heat source on a top of the substrate so that a transition can be quickly made to the optimum temperature required for the adsorption reaction or the desorption reaction. However, due to the characteristics of a conventional heat source device, it is not easy to control an amount of energy applied to the substrate and an exposure time, and thus a heat is transmitted deep into the substrate. Accordingly, after an exposure to a high temperature required for the desorption reaction, there is a delay time for cooling to a temperature required for the adsorption reaction and due to costs required for a quick cooling, the UPH is not effectively reduced compared to the above-mentioned prior art. Also, this damages a micro semiconductor device composed of various materials due to a deeply transmitted high temperature.

Therefore, due to a limitation of not being able to freely change a temperature of the substrate, an isotropic atomic layer etching treatment is inevitably performed in a limited process window.

### SUMMARY

Embodiments of the inventive concept provide a substrate treating apparatus and a substrate treating method for solving the above-mentioned problems.

Embodiments of the inventive concept provide a substrate treating apparatus and a substrate treating method for efficiently treating a substrate.

Embodiments of the inventive concept provide a substrate treating apparatus and a substrate treating method for reducing a process time while satisfying both a temperature for an adsorption reaction and a temperature for a desorption reaction.

Embodiments of the inventive concept provide a substrate treating apparatus and a substrate treating method for increasing a process window.

Embodiments of the inventive concept provide a substrate treating apparatus and a substrate treating method for heating to a high temperature while being free from a damage to a wafer and a device.

The technical objectives of the inventive concept are not limited to the above-mentioned ones, and the other unmentioned technical objects will become apparent to those skilled in the art from the following description.

The inventive concept provides a substrate treating apparatus. The substrate treating apparatus includes a chamber providing a treating space; a support unit supporting a substrate at the treating space; a gas supply unit configured to introduce a gas to the treating space; a plasma source configured to provide an energy for exciting a gas introduced to the treating space to a plasma; an exhaust unit configured to exhaust an atmosphere within the treating space to an outside of the treating space; and a heating source positioned above the support unit, and wherein the heating source applies a heating energy in a pulse form to the substrate.

In an embodiment, a pulse width of a pulse is a picosecond (ps) to a millisecond (ms).

In an embodiment, the heating source applies the pulse several times to millions of times for a time within 10 milliseconds.

In an embodiment, the heating energy heats the substrate to 400° C. or above.

In an embodiment, the heating energy applies an energy of 10 mJ/cm² or above to the substrate.

In an embodiment, the heating energy applies an energy of 10 mJ/cm² to 100 mJ/cm² to the substrate.

In an embodiment, the heating source is a flash lamp, a laser optical system or a microwave generator.

In an embodiment, the support unit includes a plate in which a flow path through which a cooling fluid flows is formed.

In an embodiment, the plasma source includes: a top electrode including a first plate transmitting a light or a microwave and a transparent conductive film stacked at the first plate; a bottom electrode provided below the substrate; and a high frequency power source applying a high frequency power to at least one of the top electrode or the bottom electrode, and wherein the heating source is provided above the top electrode.

In an embodiment, the substrate treating apparatus further includes a controller, and wherein the controller performs: a first step of controlling the gas supply unit to introduce a first process gas to the treating space, and controlling the plasma source to excite the first process gas which has been introduced to a plasma to treat the substrate; a second step of controlling the gas supply unit to introduce a purge gas to the treating space, and controlling the exhaust unit to exhaust the treating space; a third step of controlling the gas supply unit to introduce a second process gas to the treating space, controlling the plasma source to excite the second process gas which has been introduced to the plasma, and controlling the heating source to apply the heating energy as a pulse to treat the substrate; and a fourth step of controlling the gas control unit to introduce the purge gas to the treating space, and controlling the exhaust unit to exhaust the treating space, and wherein the first step to the fourth step is controlled to be sequentially repeated multiple times.

In an embodiment, the support unit comprises a plate in which a flow path through which a cooling fluid flows is formed, and therein the controller controls the cooling fluid to flow at the flow path of the plate, at the third step.

The inventive concept provides a substrate treating method. The substrate treating method includes introducing a first process gas to a treating space, and exciting the first process gas which has been introduced to a plasma to treat a substrate as a first step; introducing a purge gas to the treating space, and exhausting the treating space as a second step; introducing a second process gas to the treating space, exciting the second process gas which has been introduced to a plasma, and applying a heating energy as a pulse as a third step; and applying the purge gas to the treating space, and exhausting the treating space as a fourth step, and wherein the first step to the fourth step is sequentially repeated multiple times.

In an embodiment, a pulse width of the pulse is a picosecond (ps) to a millisecond (ms).

In an embodiment, the heating energy applies the pulse several times to millions of times for a time within 10 milliseconds.

In an embodiment, the heating energy heats the substrate to 400° C. or above.

In an embodiment, the heating energy applies an energy of 10 mJ/cm² or above to the substrate.

In an embodiment, the heating energy applies an energy of 10 mJ/cm² to 100 mJ/cm² to the substrate.

In an embodiment, the heating energy is a flash, a laser, or a microwave.

In an embodiment, a bottom surface of the substrate is cooled at the third step.

In an embodiment, the support unit includes: a chuck supporting the substrate;

and a cooling plate configured to cool the substrate, and wherein the heating source heats the substrate from a surface to within a depth of 100 μm.

In an embodiment, the support unit includes: a chuck supporting the substrate; and a cooling plate configured to cool the substrate, and wherein the heating source heats the substrate from a surface to within a depth of 200 μm, and the cooling plate cools a bottom surface of the substrate.

The inventive concept provides a substrate treating apparatus. The substrate treating apparatus includes a chamber providing a treating space; a support unit supporting a substrate at the treating space, and including a plate in which a flow path through which a cooling fluid flows is formed; a gas supply unit configured to introduce a gas to the treating space; a plasma source configured to provide an energy for exciting a gas introduced to the treating space to a plasma; an exhaust unit configured to exhaust an atmosphere within the treating space to an outside of the treating space; and a heating source positioned above the support unit, and provided as any one of a flash lamp, a laser optical system, or a microwave generator, and wherein the plasma source comprises: a top electrode including a first plate transmitting a light or a microwave and a transparent conductive film stacked at the first plate; a bottom electrode provided below the substrate; and a high frequency power source applying a high frequency power to at least one of the top electrode or the bottom electrode, and wherein the heating source is provided above the top electrode, and applies a heating energy in a pulse form of 10 mJ/cm² to 100 mJ/cm² to the substrate, and applies the pulse several times to hundreds of times for a time within a 1 millisecond.

According to an embodiment of the inventive concept, a temperature required for a desorption reaction may be reached and the desorption reaction may be obtained within a few milliseconds (ms).

According to an embodiment of the inventive concept, a substrate surface may be exposed to a high temperature for a very short time while being heated to the high temperature for a desorption reaction, so a loss of a device function and a substrate cracking phenomenon due to an exposure to the high temperature may be prevented.

According to an embodiment of the inventive concept, an adsorption process may be performed at 400° C. or above.

According to an embodiment of the inventive concept, as a process window is expanded, various types of precursors may be introduced.

According to an embodiment of the inventive concept, a substrate may be treated efficiently.

The effects of the inventive concept are not limited to the above-mentioned ones, and the other unmentioned effects will become apparent to those skilled in the art from the following description.

### BRIEF DESCRIPTION OF THE FIGURES

The above and other objects and features will become apparent from the following description with reference to the following figures, wherein like reference numerals refer to like parts throughout the various figures unless otherwise specified, and wherein:

FIG. 1 illustrates a substrate treating apparatus 1000 according to a first embodiment of the inventive concept.

FIG. 2 is an enlarged view illustrating a portion of a cross section of a top electrode 310.

FIG. 3 illustrates a state of an apparatus when performing an adsorption process.

FIG. 4 illustrates a state of the apparatus when performing a purge process after the adsorption process.

FIG. 5 illustrates a state of the apparatus when performing a desorption process.

FIG. 6 illustrates a state of the apparatus when performing a purge process after the desorption process.

FIG. 7 illustrates a substrate treating apparatus 2000 according to a second embodiment of the inventive concept.

FIG. 8 illustrates a reaction of a substrate when performing the adsorption process, the purge process after the adsorption process, the desorption process, and the purge process after the desorption process.

FIG. 9 is a flowchart of a substrate treatment method according to an embodiment of the inventive concept, and shows a power of a heating energy applied in the desorption process and a temperature change of a surface of the substrate.

FIG. 10 is a temperature profile illustrating a degree of heating for each depth of the substrate W when a pulse energy is applied.

FIG. 11 is a graph illustrating a temperature distribution for each depth of the substrate when unit pulses having different pulse widths are irradiated to the substrate.

FIG. 12 is a comparison graph of a heat up rate per second and a cool down rate per second according to a heating source.

### DETAILED DESCRIPTION

Hereinafter, embodiments of this invention will be described in detail with reference to the accompanying drawings so that those of ordinary skill in the technical field to which this invention belongs can easily implement this invention. However, the inventive concept may be implemented in various different forms and is not limited to the embodiments described herein. In addition, in describing a correct embodiment of the inventive concept in detail, when it is determined that a detailed description of related known functions or configurations may unnecessarily obscure the gist of the inventive concept, the detailed description thereof will be omitted. In addition, a same sign is used throughout the drawing for parts with similar functions and actions.

To “include” a component means that it may include more other components, not excluding other components unless otherwise stated. Specifically, the term “include” or “have” should be understood to designate that there are features, numbers, steps, operations, components, or a combination thereof described in the specification, and do not preclude the presence or addition of one or more other features or numbers, steps, operations, components, or combinations thereof.

The singular expression includes plural expressions unless the context clearly implies otherwise. In addition, shapes and sizes of elements in the drawings may be exaggerated for clearer explanation.

The term “and/or” includes any one of the listed items and all combinations of one or more. In addition, in the present specification, the term “connected” means not only a case where member A and member B are directly connected, but also a case where member C is interposed between member A and member B to indirectly connect member A and member B.

Embodiments of the inventive concept may be modified in various forms, and the scope of the inventive concept should not be construed as being limited to the following embodiments. The embodiment of the inventive concept is provided to more fully explain the inventive concept on to those with average knowledge in the art. Therefore, the shape of the elements in the drawing has been exaggerated to emphasize a clearer explanation.

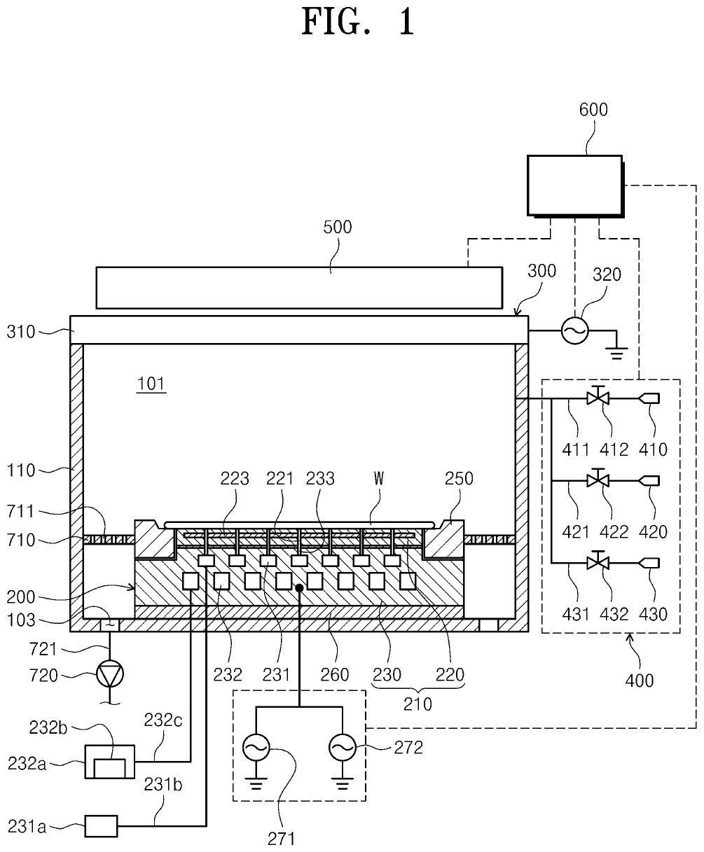

FIG. 1 illustrates a substrate treating apparatus 1000 according to a first embodiment of the inventive concept. A description will be given with reference to FIG. 1.

The substrate treatment apparatus 1000 may include a process chamber 110, a support unit 200, a gas supply unit 400, a plasma source 300, and a heating source 500. The substrate treating apparatus 1000 treats a substrate W using a plasma.

The process chamber 110 has an inner space 101 for performing a process therein. An exhaust hole 103 is formed on a bottom surface of the process chamber 110. The exhaust hole 103 is connected to an exhaust line on which a pump 720 is mounted. The reaction by-products generated in the process and a gas remaining within the inner space 101 are exhausted through the exhaust hole 103 by an exhaust pressure applied by the pump 720. In addition, the inner space 101 of the process chamber 110 is depressurized to a desired pressure by an exhaust process. The pump 720 may be a vacuum pump.

An opening (not shown) is formed on a sidewall of the process chamber 110. The opening (not shown) functions as a passage through which the substrate W enters and exits the process chamber 110. The opening (not shown) is opened and closed by a door assembly (not shown).

The support unit 200 is positioned at a lower region of the inner space 101. The support unit 200 may include an electrostatic chuck ESC. The electrostatic chuck ESC clamps the substrate W with an electrostatic force. Unlike this, the support unit 200 may support the substrate W in various ways such as a mechanical clamping.

The support unit 200 includes a dielectric plate 220 and a base plate 230. The dielectric plate 220 and the base plate 230 form the electrostatic chuck 210.

The dielectric plate 220 is positioned at a top part of the electrostatic chuck 210. The dielectric plate 220 is provided as a disk-shaped dielectric substance. The substrate W is placed on a top surface of the dielectric plate 220. In an embodiment, the top surface of the dielectric plate 220 may have a smaller radius than that of the substrate W. Therefore, the dielectric plate 220 has a first electrode 223 embedded therein.

The first electrode 223 is electrically connected to a first power source (not shown). The first power source (not shown) includes a DC power source. A switch (not shown) is installed between the first electrode 223 and the first power source (not shown). The first electrode 223 may be electrically connected to or disconnected from the first power source (not shown) by an on/off of the switch (not shown). When the switch (not shown) is turned on, a DC current is applied to the first electrode 223. An electrostatic force is applied between the first electrode 223 and the substrate W by the DC current applied to the first electrode 223, and the substrate W is adsorbed to the dielectric plate 220 by the electrostatic force.

The base plate 230 is positioned at a bottom part of the dielectric plate 220. The base plate 230 may include a material having high heat transfer and electrical transfer properties. In an embodiment, the base plate 230 may include a metal plate. In an embodiment, an entire base plate 230 may be made of a metal material. In an embodiment, the base plate 230 may be made of an aluminum material. A top surface of the base plate 230 may be stepped so that a central area is positioned higher than an edge area. The center area of the top surface of the base plate 230 has an area corresponding to an area of a bottom surface of the dielectric plate 220, and the bottom surface of the dielectric plate 220 may be positioned thereon. A focus ring 250 may be positioned at the edge area of the base plate 230.

The base plate 230 includes a first circulation flow path 231, a second circulation flow path 232, and a second supply flow path 233.

The first circulation flow path 231 is provided as a passage through which a heat transfer medium circulates. The first circulation flow path 231 may be formed in a spiral shape within the base plate 230. Alternatively, the first circulation flow path 231 may be disposed such that ring-shaped flow paths having different radii have a same center. Each of the first circulation flow paths 231 may communicate with each other. The first circulation flow paths 231 are formed at a same height.

The second supply flow path 233 upwardly extends from the first circulation flow path 231 and is provided to the top surface of the base plate 230. The second supply flow path 233 is provided in a number corresponding to that of the first supply flow path 221, and connects the first circulation flow path 231 and the first supply flow path 221. The first circulation flow path 231 is connected to a heat transfer medium storage unit 231a through a heat transfer medium supply line 231b. A heat transfer medium is stored at the heat transfer medium storage unit 231a. The heat transfer medium includes an inert gas. According to an embodiment, the heat transfer medium includes a helium (He) gas. The helium gas is supplied to the first circulation flow path 231 through the supply line 231b, and is sequentially supplied to a bottom of the substrate W through the second supply flow path 233 and the first supply flow path 221. The helium gas serves as a medium through which a heat transferred from a plasma to the substrate W is transferred to the electrostatic chuck 210.

The second circulation passage 232 is provided as a passage through which a cooling fluid circulates. The second circulation flow path 232 may be formed in a spiral shape within the base plate 230. Alternatively, the second circulation flow path 232 may be disposed such that ring-shaped flow paths having different radii have a same center. Each of the second circulation flow paths 232 may communicate with each other. The second circulation flow path 232 may have a cross-sectional area larger than that of the first circulation flow path 231. The second circulation flow paths 232 are formed at a same height. The second circulation flow path 232 may be located below the first circulation flow path 231.

The second circulation flow path 232 is connected to a cooling fluid storage unit 232a through a cooling fluid supply line 232c. A cooling fluid is stored at the cooling fluid storage unit 232a. A cooler 232b may be provided within the cooling fluid storage unit 232a. The cooler 232b cools the cooling fluid to a predetermined temperature. Alternatively, the cooler 232b may be installed at the cooling fluid supply line 232c. The cooling fluid supplied to the second circulation flow path 232 through the cooling fluid supply line 232c circulates along the second circulation flow path 232 and cools the base plate 230. While the base plate 230 is cooled, the dielectric plate 220 and the substrate W are cooled together to maintain the substrate W at a desired temperature.

The base plate 230 may be electrically connected to the first power source 271 and the second power source 272. The first power source 271 may be provided as a power source for applying a relatively low frequency power compared to the second power source 272. The second power source 272 may be provided as a power source for applying a relatively high frequency power compared to the first power source 271. The base plate 230 may function as a bottom electrode.

An insulator 240 may be provided below the base plate 260.

The gas supply unit 400 supplies a gas required for a process to the inner space 101. The gas supply unit 400 includes a first gas supply line 411 connected to the first gas supply source 410, a second gas supply line 421 connected to the second gas supply source 420, and a third gas supply line 431 connected to the third gas supply source 430. A first gas and a second gas may be reaction gases for treating the substrate, and a third gas may be a purge gas for purging. A first valve 412 may be installed at the first gas supply line 411 to open and close a passage or to adjust a flow rate of a fluid flowing through the passage. A second valve 422 may be installed at the second gas supply line 421 to open and close a passage or to adjust a flow rate of a fluid flowing through the passage. A third valve 432 may be installed at the third gas supply line 431 to open and close a passage or to adjust a flow rate of a fluid flowing through the passage.

The plasma source 300 generates a plasma from a process gas remaining in the discharge space. The discharge space may correspond to region above of the support unit 200 within the process chamber 110. The plasma source 300 may have a capacitive coupled plasma source. The plasma source 300 may include a top electrode 310, a base plate 230 functioning as a bottom electrode, and a high frequency power source 320. The top electrode 310 and the base plate 230 may be provided to face each other in a up/down direction.

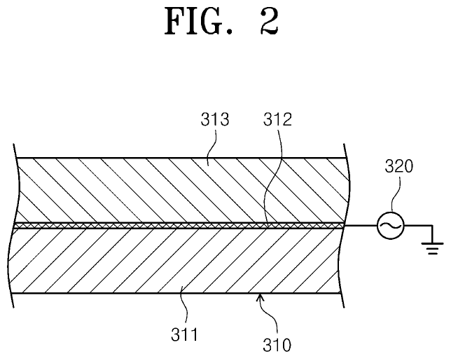

FIG. 2 is an enlarged view illustrating a portion of a cross section of the top electrode 310. The top electrode 310 will be described further with reference to FIG. 2. The top electrode 310 is configured such that a light or microwaves applied from a heating source 500 to be described below may be transferred to the substrate W without a loss (or in a state in which loss is minimized).

A transparent conductive film (transparent conductive oxide, TCO) 312 is stacked and provided at the first plate 311. The transparent conductive film 312 is provided to have a thickness at which a light or microwaves for heating the substrate W may be transmitted. In an embodiment, the transparent conductive film 312 may be an indium tin oxide (ITO). In addition, the transparent conductive film 312 may be formed of any one or more of an AZO, an FTO, an ATO, an SnO2, a ZnO, an IrO2, an RuO2, a graphene, a metal nanowire, a CNT, or a mixture thereof, or multiple overlapping. The transparent conductive film 312 is provided to have a first thickness or less. The first thickness is a thickness through which a light or microwaves may be transmitted with respect to a determined material. The first thickness varies depending on a material determined to be the transparent conductive film 312. In this description, being transmittable does not significantly affect a permeability. In an embodiment, when the transparent conductive film 312 is provided as the ITO, the first thickness may be 1 μm. The transparent conductive film 312 and the base plate 230 are combined to generate an electric field due to an RF voltage applied to one or more thereof. According to an embodiment, the transparent conductive film 312 may be grounded, and a high-frequency power may be applied to the base plate 230 by a first power source 271 and/or a second power source 272. Selectively, a power by the high frequency power source 320 may be applied to the transparent conductive film 312, and the base plate 230 may be grounded. In addition, the high frequency power may be selectively applied to both the transparent conductive film 312 and the base plate 230.

The first plate 311 is provided as a material capable of transmitting a light or microwaves for heating the substrate W. In addition, the first plate 311 is provided with a material having a corrosion resistance. As an embodiment of the first plate 311, a quartz may be provided.

A second plate 313 may be further stacked above the transparent conductive film 312. The second plate 313 is provided as a material capable of transmitting a light or microwaves for heating the substrate W. As an embodiment of the second plate 313, a quartz may be provided.

The heating source 500 heats the substrate W on the support unit 200. The heating source 500 may be a flash lamp, a laser optical system, or a microwave source. The flash lamp provides a flash with a heating energy. The laser optical system provides a laser with a heating energy. The microwave source provides microwaves with a heating energy. In an embodiment of the heating source 500, when a microwave source is provided, the heating source 500 may include a waveguide applying microwaves to within the chamber 100. The heating source 500 may apply microwaves having a frequency of 1 to 5 GHz. According to an embodiment of the inventive concept, since a surface of the substrate is selectively heated by the microwaves, a temperature increase speed and a cooling speed are high, and the surface of the substrate may be heated to a target temperature within a short time, thereby reducing a process time.

Each component of the substrate treating apparatus 1000 may be controlled by a controller 600. The controller 600 may control an entire operation of the substrate treating apparatus 1000. The controller (not shown) may include a central processing unit (CPU), a read only memory (ROM), and a random access memory (RAM). The CPU executes desired treatments such as an etching treatment according to various recipes stored in a storage area thereof.

In the recipe, a control information of the apparatus for a process condition is input. Meanwhile, a recipe indicating these programs and treating conditions may be stored in a non-transitory computer-readable medium. The non-transitory computer-readable medium refer to a medium that stores a data semi-permanently and can be read by a computer, rather than a medium that stores the data for a short period of time, such as a register, a cache, or a memory. Specifically, various applications or programs described above may be stored and provided in a non-transitory readable medium such as a CD, a DVD, a hard disk, a Blu-ray disk, a USB, a memory card, a ROM, or the like.

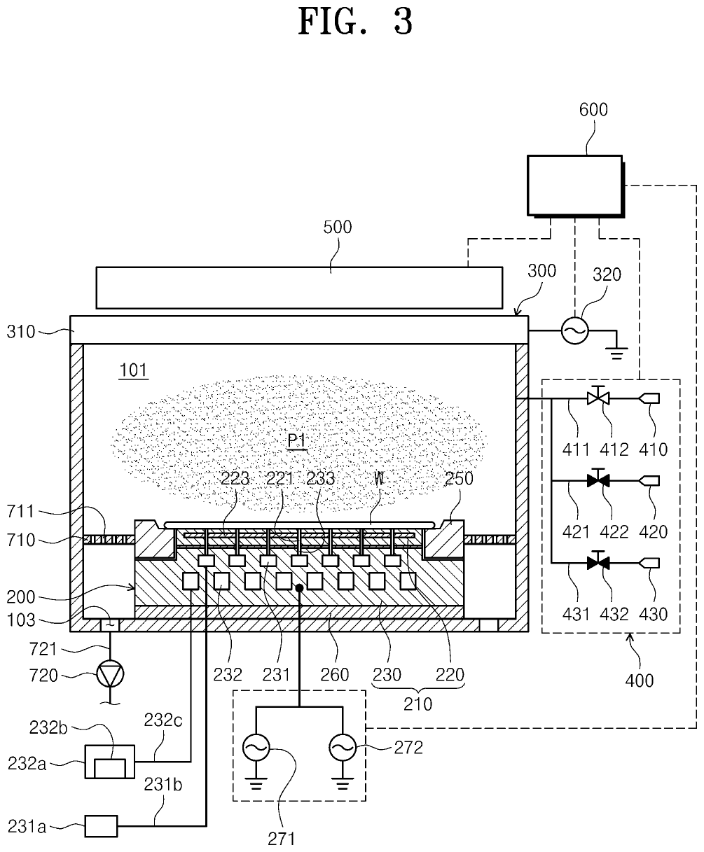

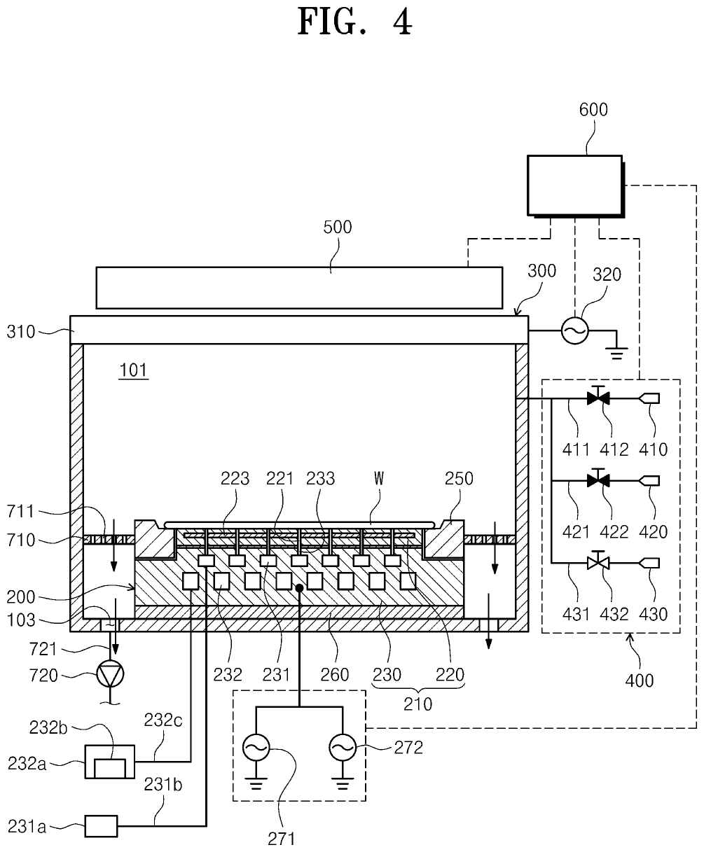

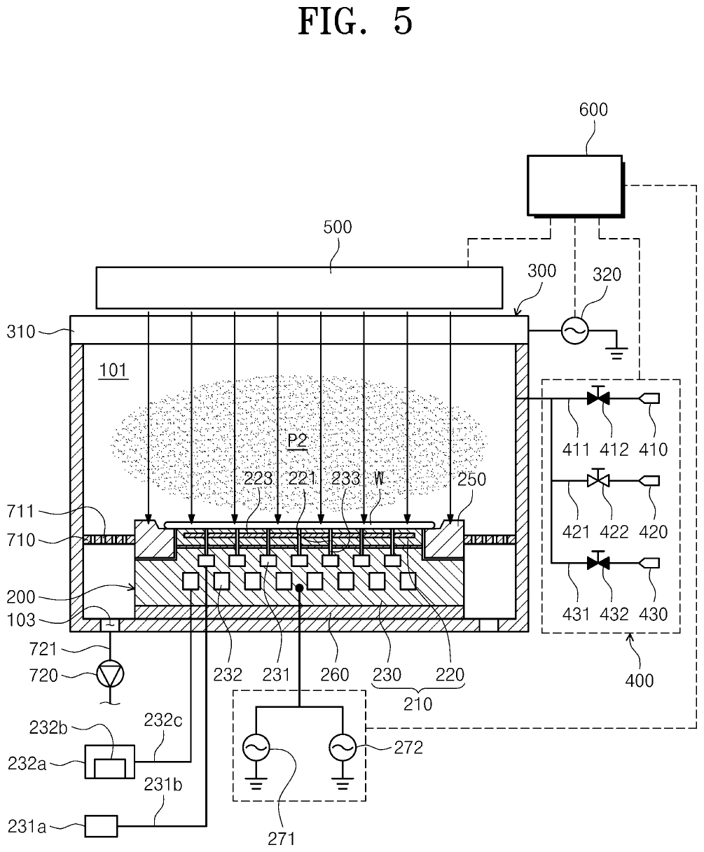

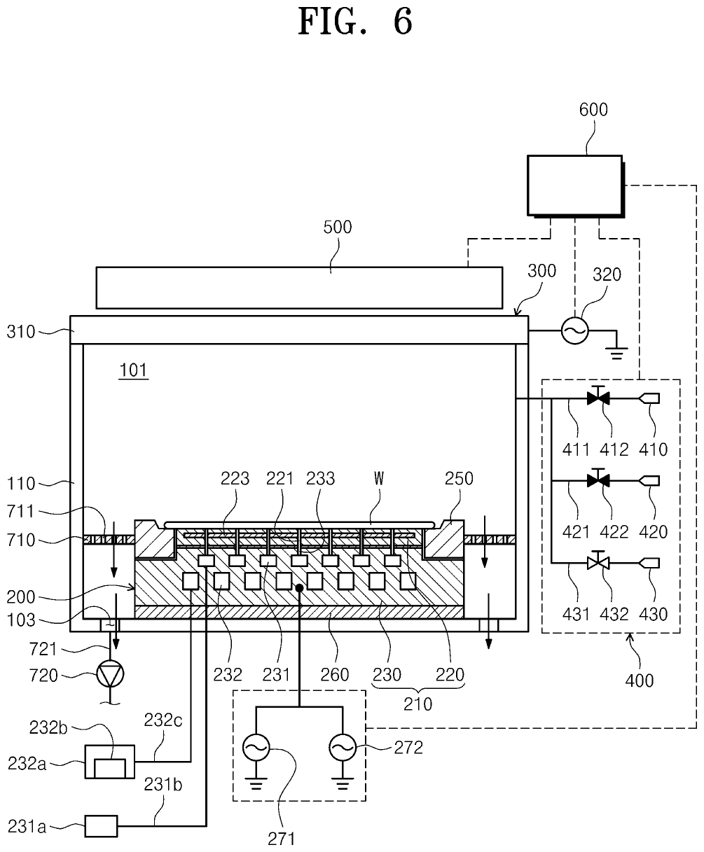

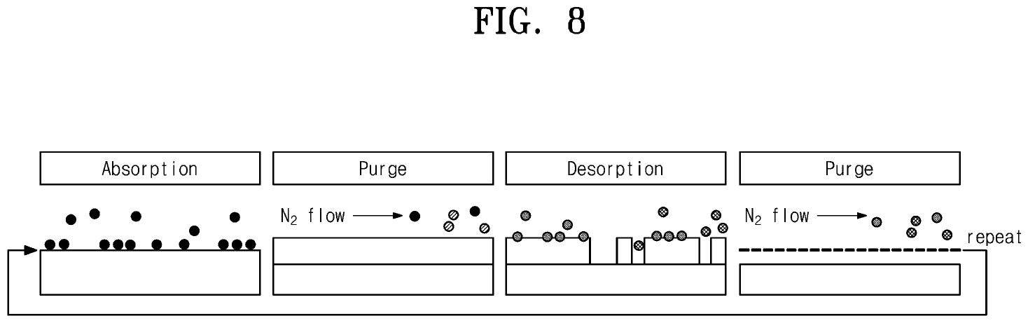

FIG. 3 to FIG. 6 describe a step of sequentially etching the substrate W. FIG. 3 illustrates a state of an apparatus when performing an adsorption process. FIG. 4 illustrates a state of the apparatus when performing a purge process after the adsorption process. FIG. 5 illustrates a state of the apparatus when performing a desorption process. FIG. 6 illustrates a state of the apparatus when performing a purge process after the desorption process. FIG. 8 illustrates a reaction of the substrate when the adsorption process, the purge process after the adsorption process, the desorption process, and the purge process after the desorption process. An atomic layer etching (ALE) using the substrate treating apparatus in accordance with an embodiment of the inventive concept will be described with reference to FIG. 3 to FIG. 6 sequentially together with FIG. 8.

See FIG. 3 and FIG. 8. FIG. 3 illustrates a state of an apparatus when performing an adsorption process. For the adsorption process, a first gas is excited into a plasma while supplying the first gas to a reaction space. The plasma excited from the first gas is adsorbed on a surface of the substrate W to modulate the surface of the substrate W. The adsorption process is performed in a state where the substrate W is at a first temperature. The first temperature is a temperature at which the plasma excited from the first gas is adsorbed on the surface of the substrate W. In an embodiment, the first temperature may be around 20° C. As the substrate W is treated at a temperature at which an adsorption of the surface of the substrate W is maximized, a time required for the adsorption reaction may be reduced. In an embodiment, the adsorption reaction may be performed within 1 second.

See FIG. 4 and FIG. 8. When the adsorption process is completed, a third gas is supplied to the inner space 101. The third gas may be a nitrogen. In addition, an atmosphere of the inner space 101 is exhausted. A process gas and process by-products remaining while purging the inner space 101 are exhausted through an exhaust hole 103. A purge process may be performed in about 5 seconds, but is not limited thereto, and it is sufficient to perform the purge process until a remaining process gas and process by-products are properly exhausted.

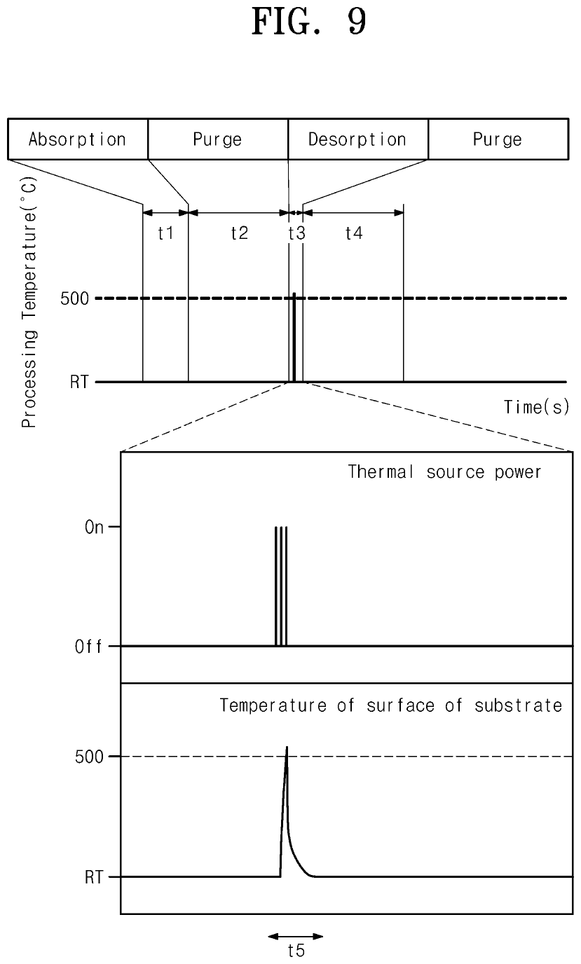

See FIG. 5 and FIG. 8. FIG. 5 illustrates a state of an apparatus when a desorption process is performed. For the desorption process, a second gas is excited with a plasma while supplying the second gas to a reaction space. The plasma excited from the second gas removes a surface of a modified substrate W. A surface of the substrate W is heated by a heating energy emitted from a heating source 500. The heating energy applies an energy of 10 mJ/cm² to 100 mJ/cm² to the substrate W. A heat on a bottom surface of the substrate W may be cooled by a cooling fluid flowing through a second circulation flow path 232 of the support unit 200. The heating energy is applied as a pulse energy. In the desorption process, the surface of the substrate W becomes a second temperature. The second temperature is a temperature at which a desorption performed by a plasma excited from the second gas is maximized. In an embodiment, the second temperature may be an ideal temperature. As the substrate W is treated at a temperature at which an adsorption of the surface of the substrate W is maximized, a time required for an adsorption reaction may be reduced. In an embodiment, the desorption reaction may be performed within 10 ms. The heating source 500 applies a pulse energy several times to millions of times for a time within 10 ms. A heating to 400° C. or above and an instantaneous cooling of the surface of the substrate W by a pulse energy emitted from the heating source 500 will be described in more detail with reference to FIG. 9 to FIG. 12.

See FIG. 6 and FIG. 8. When a desorption process is completed, a third gas is supplied to the inner space 101. The third gas may be a nitrogen. In addition, an atmosphere of the inner space 101 is exhausted. A process gas and process by-products remaining while purging the inner space 101 are exhausted through an exhaust hole 103. A purge process may be performed in about 5 seconds, but is not limited thereto, and it is sufficient to perform the purge process until a remaining process gas and process by-products are properly exhausted.

The adsorption-purge-desorption-purge process is repeated a plurality of times until a desired etching condition is achieved.

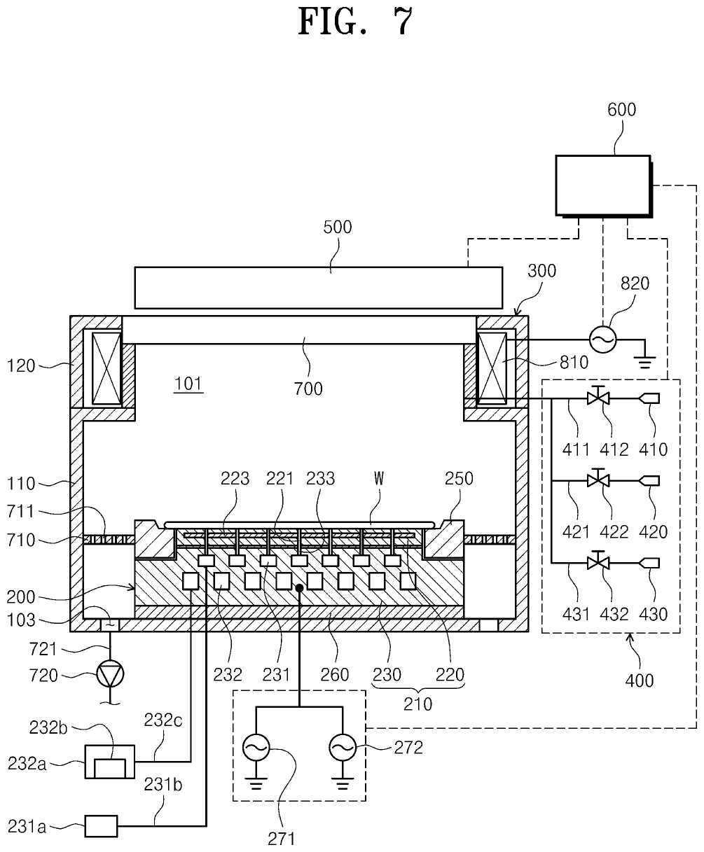

FIG. 7 illustrates a substrate treating apparatus according to a second embodiment of the inventive concept. In describing the second embodiment with reference to FIG. 7, a same configuration as the substrate treating apparatus of the first embodiment is replaced by a description of the first embodiment.

In an embodiment, a plasma source may include a cylinder-type antenna 810 and a high frequency power source 820. The cylinder-type antenna 810 is electrically connected to the high frequency power source 820. When a current from the high frequency power source 820 flows through the cylinder-type antenna 810, an electromagnetic field is formed at a discharge space. An electromagnetic field applied from the cylinder-type antenna 810 excites a process gas applied to the discharge space as to a plasma. A window 700 is provided at a ceiling of the chamber 110. The window 700 is provided with a material capable of transmitting a light or microwaves. In addition, the window 700 is provided with a corrosion-resistant material. In an embodiment, the window 700 may be provided as a quartz material. A heating source 500 is provided above the window 700.

FIG. 9 is a flowchart of a substrate treatment method according to an embodiment of the inventive concept, and shows a power of a heating energy applied in a desorption process and a temperature change of a surface of a substrate. According to an embodiment of the inventive concept, a time t1 required for an adsorption process is within 1 second. A time t3 required for the desorption process is within 10 ms.

A surface of the substrate W is heated by a heating source 500. The heating source 500 applies a heating energy as a pulse. In an embodiment, it is illustrated that a pulse energy is applied three times. However, this is illustrated for description and may be set differently according to a size and a type of energy applied. A pulse width may be set to a level of picoseconds (ps) to milliseconds (ms).

A bottom surface of the substrate W is cooled by a support unit 200. Since only a surface to which the substrate W is detached is heated while the bottom surface of the substrate W is cooled, it is possible to prevent the substrate W from being cracked due to a high-temperature process.

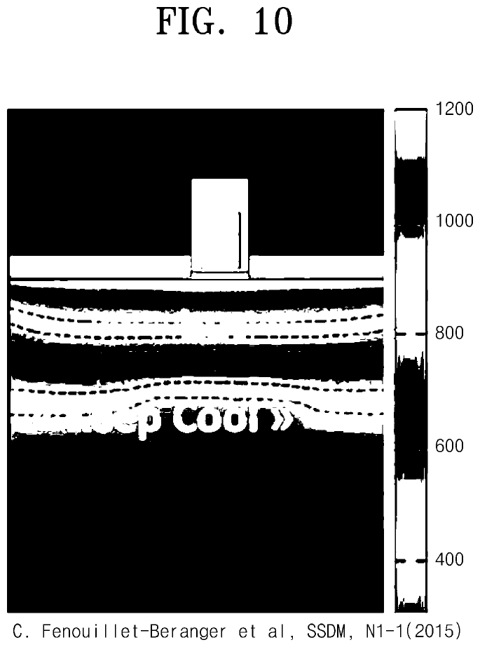

FIG. 10 is a temperature profile illustrating a degree of heating for each depth of a substrate W when a pulse energy is applied. This is a result of having performed with a laser having a wavelength of 308 nm and a pulse duration of 200 ns. When the pulse energy is applied, a surface of the substrate may be rapidly heated within a short time.

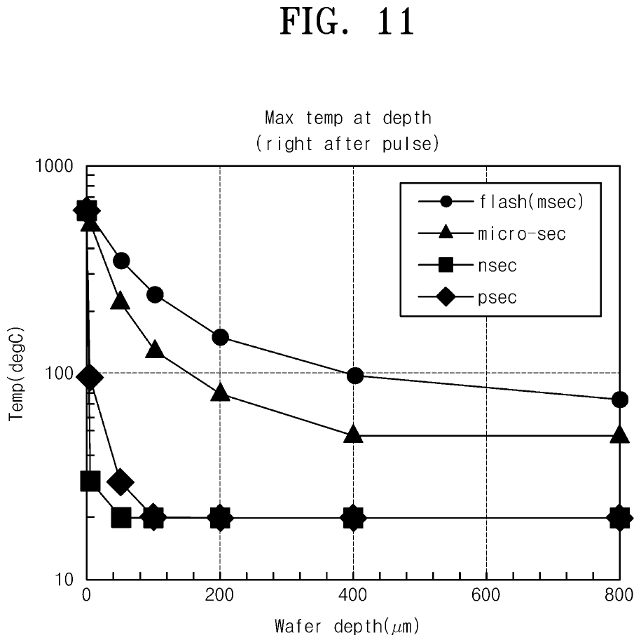

FIG. 11 is a graph illustrating a temperature distribution for each depth of a substrate unit pulses having different pulse widths are irradiated to the substrate. Referring to FIG. 11, it may be seen that if a picosecond (psec) is applied and if a nanosecond (nsec) is applied, a region within a depth of 100 μm is heated, and a region deeper than 100 μm is not heated. According to an embodiment of the inventive concept, the substrate W is heated by applying a heating energy in a pulse form having a pulse width of a picosecond (psec) or a nanosecond (nsec) from a top of the substrate W to a depth of within 100 In an embodiment, when a heating energy having a pulse width of a microsecond (micro-sec) or a millisecond (msec) is applied, the heating energy is heated from 200 μm to around 100° C., but a temperature for each depth of the substrate is controlled by using a cooling system of a substrate support unit.

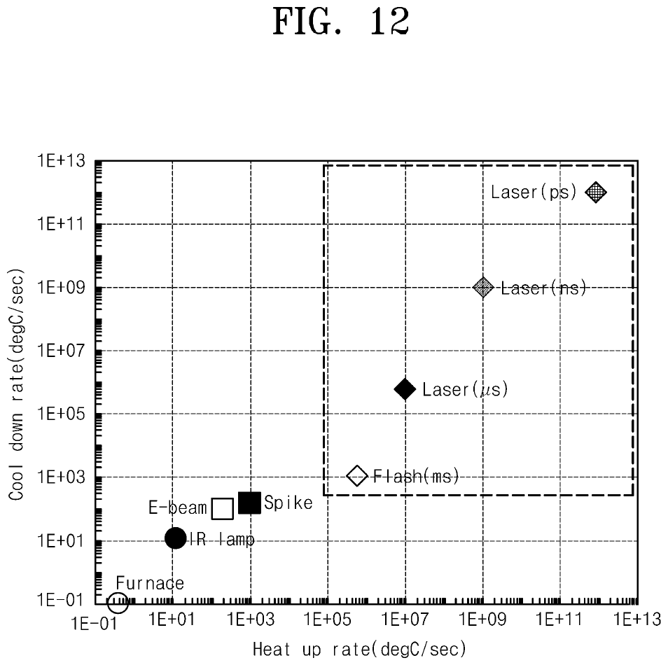

FIG. 12 is a comparison graph of a heat up rate per second and a cooling down rate per second according to a heating source. A flash, a μs laser, an ns laser, and a ps laser have an excellent heating capacity per second and a time required for cooling is short. Although not shown in the drawings, since a wavelength of microwaves are much longer than a thickness and a spacing of a metal wiring layer of a semiconductor chip, a depth at which the microwaves penetrate into a metal material is less than several According to an embodiment, a surface of a substrate or a die is heated by a microwave thermal treatment, so that a surface temperature can be rapidly increased to a target temperature and a cool-down can be carried out. According to an embodiment of the inventive concept, a flash, a laser, or microwaves are applied as the heating energy.

According to embodiments of the inventive concept, a temperature of a desorption process may be controlled at a level of picoseconds (ps) to milliseconds (ms). In addition, a high-speed t-ALE process in which a desorption process time is shortened to a level of picoseconds (ps) to several milliseconds (ms) is possible.

According to embodiments of the inventive concept, a rapid temperature increase may be implemented. In addition, since a wafer W is supported by a support unit 200 and a bottom surface thereof may be cooled by a cooling fluid, the wafer W may be prevented from cracking despite a process using a high temperature.

According to embodiments of the inventive concept, a temperature may be controlled at a high temperature in a short time, thereby widening a selection range of a precursor. That is, the precursor requiring a higher reaction temperature may be used. In addition, it is easy to remove by-products having a relatively high boiling point.

Embodiments of the inventive concept may be applied to an anisotropic ALE as well as an isotropic ALE.

The effects of the inventive concept are not limited to the above-mentioned effects, and the unmentioned effects can be clearly understood by those skilled in the art to which the inventive concept pertains from the specification and the accompanying drawings.

Although the preferred embodiment of the inventive concept has been illustrated and described until now, the inventive concept is not limited to the above-described specific embodiment, and it is noted that an ordinary person in the art, to which the inventive concept pertains, may be variously carry out the inventive concept without departing from the essence of the inventive concept claimed in the claims and the modifications should not be construed separately from the technical spirit or prospect of the inventive concept.

What is claimed is:

1. A substrate treating apparatus comprising:
a chamber providing a treating space;
a support unit supporting a substrate at the treating space;
a gas supply unit configured to introduce a gas to the treating space;
a plasma source configured to provide an energy for exciting a gas introduced to the treating space to a plasma;
an exhaust unit configured to exhaust an atmosphere within the treating space to an outside of the treating space; and
a heating source positioned above the support unit, and
wherein the heating source applies a heating energy in a pulse form to the substrate.

2. The substrate treating apparatus of claim 1, wherein a pulse width of a pulse is a picosecond (ps) to a millisecond (ms).

3. The substrate treating apparatus of claim 1, wherein the heating source applies the pulse several times to millions of times for a time within 10 milliseconds.

4. The substrate treating apparatus of claim 1, wherein the heating energy heats the substrate to 400° C. or above.

5. The substrate treating apparatus of claim 1, wherein the heating energy applies an energy of 10 mJ/cm² or above to the substrate.

6. The substrate treating apparatus of claim 2, wherein the heating energy applies an energy of 10 mJ/cm² to 100 mJ/cm² to the substrate.

7. The substrate treating apparatus of claim 1, wherein the heating source is a flash lamp, a laser optical system or a microwave generator.

8. The substrate treating apparatus of claim 1, wherein the support unit includes a plate in which a flow path through which a cooling fluid flows is formed.

9. The substrate treating apparatus of claim 1, wherein the plasma source comprises:
a top electrode including a first plate transmitting a light or a microwave and a transparent conductive film stacked at the first plate;
a bottom electrode provided below the substrate; and
a high frequency power source applying a high frequency power to at least one of the top electrode or the bottom electrode, and
wherein the heating source is provided above the top electrode.

10. The substrate treating apparatus of claim 1, further comprises a controller, and
wherein the controller configured to perform:
a first step of controlling the gas supply unit to introduce a first process gas to the treating space, and controlling the plasma source to excite the first process gas which has been introduced to a plasma to treat the substrate;
a second step of controlling the gas supply unit to introduce a purge gas to the treating space, and controlling the exhaust unit to exhaust the treating space;
a third step of controlling the gas supply unit to introduce a second process gas to the treating space, controlling the plasma source to excite the second process gas which has been introduced to the plasma, and controlling the heating source to apply the heating energy as a pulse to treat the substrate; and
a fourth step of controlling the gas control unit to introduce the purge gas to the treating space, and controlling the exhaust unit to exhaust the treating space, and
wherein the first step to the fourth step is controlled to be sequentially repeated multiple times.

11. The substrate treating apparatus of claim 10, wherein the support unit comprises a plate in which a flow path through which a cooling fluid flows is formed, and
wherein the controller configured to control the cooling fluid to flow at the flow path of the plate, at the third step.

12. The substrate treating apparatus of claim 1, wherein the support unit comprises:
a chuck supporting the substrate; and
a cooling plate configured to cool the substrate, and
wherein the heating source heats the substrate from a surface to within a depth of 100 μm.

13. The substrate treating apparatus of claim 1, wherein the support unit comprises:
a chuck supporting the substrate; and
a cooling plate configured to cool the substrate, and
wherein the heating source heats the substrate from a surface to within a depth of 200 μm, and
the cooling plate cools a bottom surface of the substrate.

14. A substrate treating apparatus comprising:
a chamber providing a treating space;
a support unit supporting a substrate at the treating space, and including a plate in which a flow path through which a cooling fluid flows is formed;
a gas supply unit configured to introduce a gas to the treating space;
a plasma source configured to provide an energy for exciting a gas introduced to the treating space to a plasma;
an exhaust unit configured to exhaust an atmosphere within the treating space to an outside of the treating space; and
a heating source positioned above the support unit, and provided as any one of a flash lamp, a laser optical system, or a microwave generator, and
wherein the plasma source comprises:
a top electrode including a first plate transmitting a light or a microwave and a transparent conductive film stacked at the first plate;
a bottom electrode provided below the substrate; and
a high frequency power source applying a high frequency power to at least one of the top electrode or the bottom electrode, and
wherein the heating source is provided above the top electrode, and
applies a heating energy in a pulse form of 10 mJ/cm² to 100 mJ/cm² to the substrate, and
applies the pulse several times to hundreds of times for a time within a 1 millisecond.
